(19) United States
(12) Patent Application Publication
(10) Pub. No.: US 2024/0431146 A1
(43) Pub. Date: Dec. 26, 2024

(54) DISPLAY PANEL AND DISPLAY DEVICE

(71) Applicant: HEFEI VISIONOX TECHNOLOGY CO., LTD., Hefei (CN)

(72) Inventors: Yuan YAO, Hefei (CN); Fanle MENG, Hefei (CN); Yiming XIAO, Hefei (CN); Haohan ZHANG, Hefei (CN); Liusong NI, Hefei (CN); Mingchen LI, Hefei (CN)

(73) Assignee: HEFEI VISIONOX TECHNOLOGY CO., LTD., Hefei (CN)

(21) Appl. No.: 18/645,834

(22) Filed: Apr. 25, 2024

Related U.S. Application Data
(63) Continuation of application No. PCT/CN2024/081989, filed on Mar. 15, 2024.

(30) Foreign Application Priority Data
Jun. 20, 2023 (CN) 202310740412.8

(51) Int. Cl. H10K 59/122; H10K 59/35

(52) U.S. Cl. CPC H10K 59/122; H10K 59/353

(57) ABSTRACT

A display panel and a display device. The display panel has a first display region and a second display region. The display panel includes: a substrate; a plurality of sub-pixels provided on the substrate; and a partition structure provided on a side of the substrate. The partition structure defines a plurality of partition openings. The partition openings each include a first opening located in the first display region and a second opening located in the second display region. The sub-pixels are provided in the first opening and the second opening, respectively. The plurality of sub-pixels includes first sub-pixels and second sub-pixels. A distance between centers of the first sub-pixel and the adjacent second sub-pixel located in the first display region is less than a distance between centers of the first sub-pixel and the adjacent second sub-pixel located in the second display region.

### CROSS-REFERENCE TO RELATED APPLICATIONS

This application is a continuation application of International Application No. PCT/CN2024/081989, filed Mar. 15, 2024, and claims priority to Chinese patent application No. 202310740412.8, filed on Jun. 20, 2023, entitled “DISPLAY PANEL AND DISPLAY DEVICE”, the content of which is hereby incorporated by reference in its entirety.

### TECHNICAL FIELD

The present disclosure relates to the field of display technology, and in particular, to a display panel and a display device.

### BACKGROUND

In recent years, organic light-emitting diode (OLED) has attracted widespread attention due to its huge application market in the display field. Compared with other display technologies, OLED modules have many advantages, such as wide viewing angle, fast response, no need for backlighting, and flexible display.

### SUMMARY

According to an aspect of the present disclosure, a display panel is provided. The display panel has a first display region and a second display region. The display panel includes: a substrate; a plurality of sub-pixels provided on the substrate; and a partition structure provided on a side of the substrate. The partition structure defines a plurality of partition openings. The partition openings include a first opening located in the first display region and a second opening located in the second display region. The plurality of sub-pixels are provided in the first opening and the second opening, respectively. The plurality of sub-pixels includes a first sub-pixel and a second sub-pixel. A distance between centers of the first sub-pixel and the adjacent second sub-pixel located in the first display region is less than a distance between centers of the first sub-pixel and the adjacent second sub-pixel located in the second display region.

According to another aspect of the present disclosure, a display panel is provided. The display panel has a first display region and a second display region. The display panel includes: a substrate; a plurality of sub-pixels provided on the substrate; and a partition structure provided on a side of the substrate. The partition structure defines a plurality of partition openings. The partition openings include a first opening located in the first display region and a second opening located in the second display region. The plurality of sub-pixels are provided in the first openings and the second opening respectively. The plurality of sub-pixels includes a plurality of first sub-pixels. A distance between centers of two adjacent first sub-pixels located in the first display region is less than a distance between centers of two adjacent first sub-pixels located in the second display region.

According to yet another aspect of the present disclosure, a display panel is provided. The display panel has a first display region and a second display region. The display panel includes: a substrate; and a plurality of sub-pixels provided on the substrate. The plurality of sub-pixels include a first sub-pixel and a second sub-pixel. A distance between centers of the first sub-pixel and the adjacent second sub-pixel located in the first display region is less than a distance between centers of the first sub-pixel and the adjacent second sub-pixel located in the second display region.

According to yet another aspect of the present disclosure, a display panel is provided. The display panel has a first display region and a second display region. A pixel density of the first display region is greater than a pixel density of the second display region.

According to yet another aspect of the present disclosure, a display device is provided, including the display panel of any of the above aspects.

The details of one or more embodiments of the invention are set forth in the accompanying drawings and the description below. Other features, objects, and advantages of the invention will be apparent from the description and drawings, and from the claims.

### BRIEF DESCRIPTION OF THE DRAWINGS

In order to more clearly illustrate the technical solutions in the embodiments of the present disclosure or the prior art, the drawings needed to be used in the description of the embodiments or the prior art will be briefly introduced below. Apparently, the following described drawings are merely for the embodiments of the present disclosure, and other drawings can be derived by those of ordinary skill in the art without any creative effort.

FIG. 1 is a schematic view of a display panel according to embodiment of the present disclosure.

FIG. 2 is a schematic cross-sectional view of a first display region according to an embodiment of the present disclosure.

FIG. 3 is a schematic cross-sectional view of a second display region according to an embodiment of the present disclosure.

FIG. 4 is a schematic top view of a first display region of a display panel according to an embodiment of the present disclosure.

FIG. 5 is a schematic top view of a second display region of a display panel according to an embodiment of the present disclosure.

FIG. 6 is a schematic view of a substrate to be evaporated according to an embodiment of the present disclosure.

FIG. 7 is a schematic view of a first sub-pixel region of the substrate to be evaporated when a sub-pixel production is finished according to an embodiment of the present disclosure.

FIG. 8 is a schematic view of a second sub-pixel region of the substrate to be evaporated when a sub-pixel production is finished according to an embodiment of the present disclosure.

FIG. 9 is a schematic view of a third sub-pixel region of the substrate to be evaporated when a sub-pixel production is finished according to an embodiment of the present disclosure.

FIG. 10 is a schematic cross-sectional view of a display panel according to an embodiment of the present disclosure.

FIG. 11 is a schematic top view of a first display region of a display panel according to another embodiment of the present disclosure.

FIG. 12 is a schematic top view of a second display region of a display panel according to another embodiment of the present disclosure.

### DETAILED DESCRIPTION

In order to facilitate understanding of the present disclosure, the present disclosure will be described more fully below with reference to the relevant drawings. The preferred embodiments of the present disclosure are shown in the accompanying drawings. However, the present disclosure may be implemented in many different forms and is not limited to the embodiments described herein. Rather, these embodiments are provided so that a thorough understanding of the disclosure of the present disclosure will be provided.

Furthermore, the present disclosure is described in detail in conjunction with simplified cross sectional views. In describing the embodiments of the present disclosure in detail, for convenient description, sectional views showing structures of the device are not drawn to scale, and these simplified cross sectional views are only examples and should not limit the scope of protection of the present disclosure.

Display panels of some display devices in the related art includes a main display region and a secondary display region. The secondary display region is used to display some auxiliary information. Since the secondary display region is only used to display auxiliary information, requirements of the secondary display region for pixels per inch (PPI) are not high. However, in the related art, the main display region and the secondary display region of the display panel have the same PPI, resulting in high production costs. Taking smart watches as an example, some smart watches on the market include display panels with a circular main display region and an annular secondary display region arranged around the main display region. The secondary display region is usually used to display some secondary auxiliary information. At present, the main display region and the secondary display region of the display panel of this kind of smart watch usually have the same PPI, resulting in high production costs. After careful investigation and research, the inventor found that under the limitations of conventional production processes, if different areas of a display panel have different PPIs, the product yield will be significantly reduced. This is also the main reason why the main display region and the secondary display region of the above display panel have the same PPI.

Specifically, the production process of sub-pixels of the display panel in the related art involves using a fine metal mask (FMM) to evaporate an organic light-emitting material onto a substrate to be evaporated. In order to realize that the PPI of the main display region and the PPI of the secondary display region are different, the spacing between evaporation openings in different areas on the FMM needs to be set differently. However, the FMM will be subjected to uneven force when performing welding, and prone to produce large wrinkles, which will reduce the production accuracy of sub-pixels and even cause color mixing problems, which in turn will lead to a decrease in product yield. Therefore, in order to ensure product yield, most manufacturers gave up the solution of different areas of a display panel having different PPIs.

In view of the above problems, embodiments of the present disclosure provide a display panel 100, which aims to reduce the production cost of the display panel 100 having a main display region and a secondary display region.

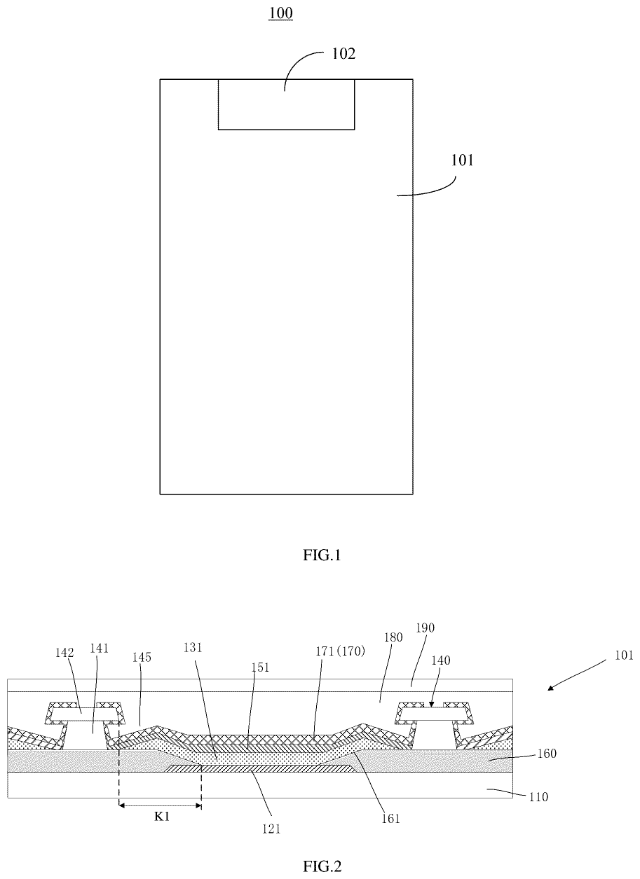

As shown in FIGS. 1 to 5, the display panel 100 according to the embodiments of the present disclosure has a first display region 101 and a second display region 102. The display panel 100 includes a substrate 110, a plurality of sub-pixels configured to form a plurality of pixel units, and a partition structure 140. The plurality of sub-pixels are provided on the substrate 110. The partition structure 140 is provided on a side of the substrate 110. The partition structure 140 defines a plurality of partition openings. The partition openings include a first opening 145 located in the first display region 101 and a second opening 146 located in the second display region 102. The sub-pixels are provided in the first opening 145 and the second opening 146, respectively. The plurality of sub-pixels include first sub-pixels 11 and second sub-pixels 12. A distance X1 between the centers of the first sub-pixel 11 and the adjacent second sub-pixel 12 located in the first display region 101 is less than a distance X2 between the centers of the first sub-pixel 11 and the adjacent second sub-pixel 12 located in the second display region 102.

The display panel 100 may be an organic light-emitting diode (OLED) display panel 100. The substrate 110 may include an underlayer and a driving circuit layer provided on the underlayer. The underlayer can be a rigid s underlayer or a flexible underlayer. When the underlayer is a rigid underlayer, the substrate can be made of glass or silicon wafer, etc. When the underlayer is a flexible underlayer, the substrate can be made of metal foil, polymer plastic, etc.

The first sub-pixel 11 and the second sub-pixel 12 that are adjacent to each other may or may not belong to the same pixel unit. The first sub-pixel 11 is configured to emit light of a first color, and the second sub-pixel 12 is configured to emit light of a second color.

The partition structure 140 defines the plurality of partition openings, and each sub-pixel is provided in the corresponding partition opening, so that the sub-pixels can be isolated from each other.

In some embodiments, the distance X1 between the centers of any first sub-pixel 11 and the adjacent second sub-pixel 12 located in the first display region 101 is less than the distance X2 between the centers of any first sub-pixel 11 and the adjacent second sub-pixel 12 located in the second display region 102.

In the display panel 100 according to the embodiments of the present disclosure, the distance X1 between the centers of the first sub-pixel 11 and the second sub-pixel 12 that are adjacent to each other in the first display region 101 is less than the distance X2 between the centers of the first sub-pixel 11 and the second sub-pixel 12 that are adjacent to each other in the second display region 102. As such, at least one of the first sub-pixels 11 and the second sub-pixels 12 in the first display region 101 are more densely distributed than the corresponding sub-pixels of the same color in the second display region 102, so that the PPI of the first display region 101 is greater than the PPI of the second display region 102. When the display panel 100 is in use, the first display region 101 can be used as the main display region for displaying relatively important information, and the second display region 102 can be used as the secondary display for displaying secondary auxiliary information. In the display panel 100 according to the embodiments of the present disclosure, the first display region 101 and the second display region 102 have different PPI, which is beneficial to reduce the production cost of the display panel 100.

In addition, product yield of the display panel 100 according to the embodiments of the present disclosure will not be decreased due to the difference in PPIs of the first display region 101 and the second display region 102. In order to illustrate this point, embodiments of a production method of the display panel 100 according to the embodiments of the present disclosure are described.

The display panel 100 according to the embodiments of the present disclosure isolates the sub-pixels through the partition structure 140. The production method of the display panel 100 adopting the partition structure 140 can be different from a production method of a conventional display panel. Such difference mainly lies in the production process of the sub-pixels. As shown in FIG. 6, a first sub-pixel region 201, a second sub-pixel region 202, and a third sub-pixel region 203 are provided on the substrate 200 to be evaporated in advance. The first sub-pixel region 201 is used to accommodate the first sub-pixels. The second sub-pixel region 202 is configured to accommodate the second sub-pixels, and the third sub-pixel region 203 is configured to accommodate third sub-pixels.

In some embodiments, the sub-pixel production process is as follows.

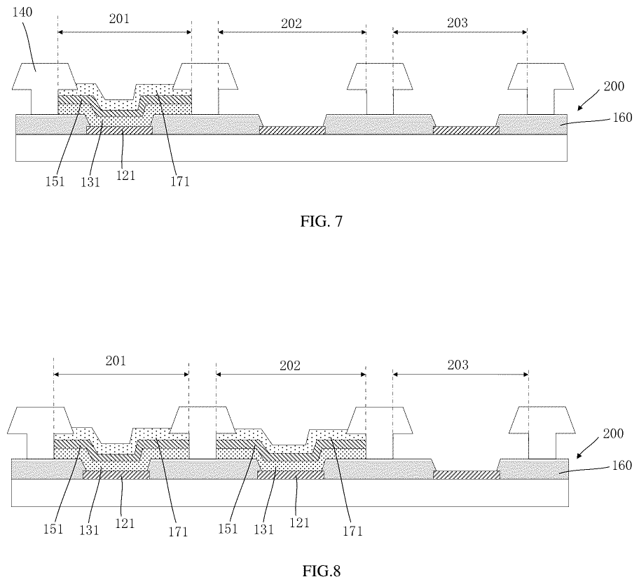

Referring to FIG. 7, firstly, a first color luminescent material layer, a second electrode material layer, and a first packaging material layer are sequentially evaporated on the substrate 200 to be evaporated, then the first color luminescent material layer, the second electrode material layer, and the first packaging material layer are patterned by photolithography process, only the portions of the first color luminescent material layer, the second electrode material layer, and the first packaging material layer located in the first sub-pixel region 201 are retained, so that a light-emitting function portion 131 configured to emit the light of the first color, a corresponding second electrode portion 151, and a packaging portion 171 are formed.

Referring to FIG. 8, then, a second color luminescent material layer, a second electrode material layer, and a first packaging material layer are sequentially evaporated on the substrate 200 to be evaporated. Then, the second color luminescent material layer, the second electrode material layer, and the first packaging material layer are patterned by a photolithography process, only the portions of the second color luminescent material layer, the second electrode material layer, and the first packaging material layer located in the second sub-pixel region 202 are retained, so that a light-emitting function portion 131 configured to emitting the light of the second color, a corresponding second electrode portion 151, and a packaging portion 171 are formed.

Referring to FIG. 9, thereafter, a third color luminescent material layer, a second electrode material layer, and a first packaging material layer are sequentially evaporated on the substrate 200 to be evaporated. Then, the third color luminescent material layer, the second electrode material layer, and the first packaging material layer are patterned by a photolithography process, only the portions of the third color luminescent material layer, the second electrode material layer, and the first packaging material layer located in the third sub-pixel region 203 are retained, so that a light-emitting function portion 131 configured to emitting the light of the third color, a corresponding second electrode portion 151, and a packaging portion 171 are formed.

Through the above steps, a sub-pixel and a packaging portion 171 are formed in each sub-pixel region. Each sub-pixel includes a first electrode portion 121, the light-emitting function portion 131, and the second electrode portion 151. The light-emitting function portions 131 of the sub-pixels of different colors are configured to emit light of different colors.

It can be seen from the above production process that, the above production process can replace the FMM that needs to be used in the conventional production process. Since the production accuracy of the photolithography process is significantly higher than the accuracy of evaporation using FMM. Therefore, the above production process can achieve higher PPI, and also, the problem of product yield reduction caused by FMM welding can be avoided.

To sum up, in the display panel 100 according to the embodiments of the present disclosure, the first display region 101 and the second display region 102 have different PPIs, which is beneficial to reduce the production cost of the display panel 100. In addition, during the production process of the display panel 100, the photolithography process can be used to replace the FMM, thereby avoiding the problem of product yield reduction caused by the FMM welding.

In some embodiments, the plurality of sub-pixels further include third sub-pixels 13, and a distance Y1 between the centers of the first sub-pixel 11 and the adjacent third sub-pixel 13 located in the first display region 101 is less than a distance Y2 between the centers of the first sub-pixel 11 and the adjacent third sub-pixel 12 located in the second display region 102. As such, at least one of the first sub-pixels 11 and the third sub-pixels 13 in the first display region 101 is more densely distributed than the corresponding sub-pixels of the same color in the second display region 102.

In some embodiments, the distance Y1 between the centers of any first sub-pixel 11 and the adjacent third sub-pixel 13 located in the first display region 101 is less than the distance Y2 between the centers of any first sub-pixel 11 and the adjacent third sub-pixel 12 located in the second display region 102.

The first sub-pixel 11 and the third sub-pixel 13 that are adjacent to each other may or may not belong to the same pixel unit. The third sub-pixel 13 is configured to emit light of the third color. The light of the first color, the light of the second color, and the light of the third color are lights of three different colors. For example, the light of the first color may be red light, the light of the second color may be green light, and the light of the third color may be blue light.

In some embodiments, the distance Z1 between the centers of the second sub-pixel 12 and the adjacent third sub-pixel 13 located in the first display region 101 is less than the distance Z2 between the centers of the second sub-pixel 12 and the adjacent third sub-pixel 13 located in the second display region 102. As such, the first sub-pixel 11, the second sub-pixel 12, and the third sub-pixel 13 in the first display region 101 are more densely distributed than the first sub-pixel 11, the second sub-pixel 12, and the third sub-pixel 13 in the second display region 102 respectively.

In some embodiments, the distance Z1 between the centers of any second sub-pixel 12 and the adjacent third sub-pixel 13 located in the first display region 101 is less than the distance Z2 between the centers of any second sub-pixel 12 and the adjacent third sub-pixel 13 located in the second display region 102.

The second sub-pixel 12 and the third sub-pixel 13 that are adjacent to each other may or may not belong to the same pixel unit.

The term “adjacent” used herein to define the relationship between two different types of sub-pixels (for example, between a first sub-pixel 11 and a second sub-pixel 12, between a first sub-pixel 11 and a third sub-pixel 13, or between a second sub-pixel 12 and a third sub-pixel 13) means that the two sub-pixels are directly adjacent to each other, that is, there are no other sub-pixels between the two sub-pixels.

In some embodiments, as shown in FIGS. 2 to 5, in the first display region 101, a first spacing H1 is defined between the first opening 145 in which the first sub-pixel 11 is provided and the adjacent first opening 145 in which the second sub-pixel 12 is provided. In the second display region 102, a second spacing H2 is defined between the second opening 146 in which the first sub-pixel 11 is provided and the adjacent second opening 146 in which the second sub-pixel 12 is provided. The first spacing H1 is less than the second spacing H2.

In some embodiments, any first spacing H1 is less than any second spacing H2.

By configuring the first spacing H1 to be less than the second spacing H2, it is beneficial to enable the distance X1 between the centers of the first sub-pixel 11 and the second sub-pixel 12 located in the first display region 101 to be less than the distance X2 between the centers of the first sub-pixel 11 and the second sub-pixel 12 in the second display region 102.

In some embodiments, in the first display region 101, a third spacing H3 is defined between the first opening 145 in which the first sub-pixel 11 is provided and the adjacent first opening 145 in which the third sub-pixel 13 is provided. In the second display region 102, a fourth spacing H4 is defined between the second opening 146 in which the first sub-pixel 11 is provided and the adjacent second opening 146 in which the third sub-pixel 13 is provided. The third spacing H3 is less than the fourth spacing H4.

In some embodiments, any third spacing H3 is less than any fourth spacing H4.

By configuring the third spacing H3 to be less than the fourth spacing H4, it is beneficial to enable the distance Y1 between the centers of the first sub-pixel 11 and the third sub-pixel 13 located in the first display region 101 to be less than the distance Y2 between the centers of the first sub-pixel 11 and the third sub-pixel 13 located in the second display region 102.

In some embodiments, in the first display region 101, a fifth spacing H5 is defined between the first opening 145 in which the second sub-pixel 11 is provided and the adjacent first opening 145 in which the third sub-pixel 13 is provided. In the second display region 102, a sixth spacing H6 is defined between the second opening 146 in which the second sub-pixel 12 is provided and the adjacent second opening 146 in which the third sub-pixel 13 is provided. The fifth spacing H5 is less than the sixth spacing H6.

In some embodiments, any fifth spacing H5 is less than any sixth spacing H6.

By configuring the fifth spacing H5 to be less than the sixth spacing H6, it is beneficial to enable a distance Z1 between the centers of the second sub-pixel 12 and the third sub-pixel 13 located in the first display region 101 to be less than a distance Z2 between the centers of the second sub-pixel 12 and the third sub-pixel 13 located in the first display region 101.

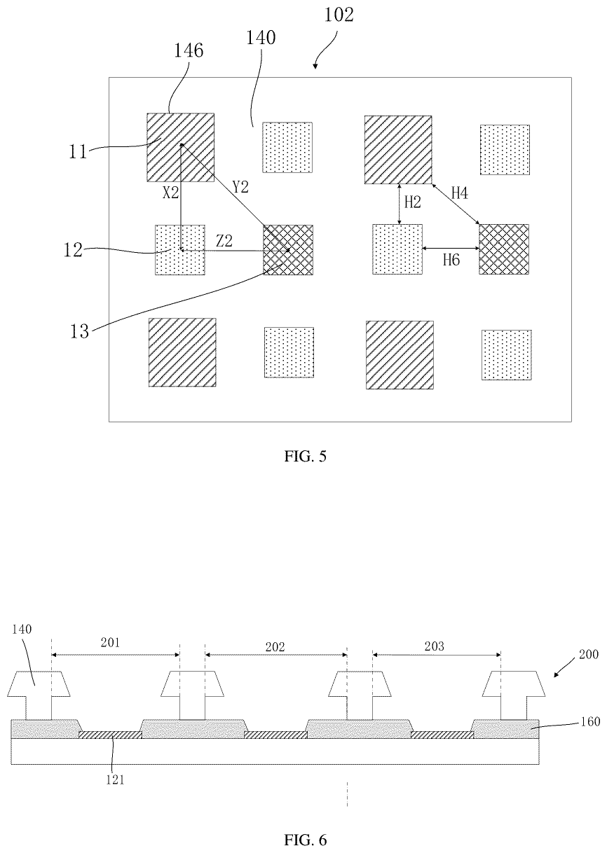

In some embodiments, as shown in FIGS. 4 and 5, the area of the first opening 145 in which the first sub-pixel 11 is provided is less than or equal to the area of the second opening 146 in which the first sub-pixel 11 is provided. In some embodiments, the area of the first opening 145 in which the second sub-pixel 12 is provided is less than or equal to the area of the second opening 146 in which the second sub-pixel 12 is provided. In some embodiments, the area of the first opening 145 in which the third sub-pixel 13 is provided is less than or equal to the area of the second opening 146 in which the third sub-pixel 13 is provided. In the case where the PPI of the first display region 101 is greater than the PPI of the second display region 102, the area of the first opening 145 in the first display region 101 where the sub-pixel of a certain color is provided can be less than or equal to the area of the second opening 146 in the second display region 101 where the sub-pixel of the same color is provided. It should be understood that when the area of the second opening 146 in which the sub-pixel of the same color in the second display region 102 is greater, correspondingly, the area of the sub-pixel in the second display region 102 can also be set to greater, which is beneficial to the aperture ratio of the second sub-pixel.

In some embodiments, a distance Q1 between the centers of any two adjacent first sub-pixels 11 located in the first display region 101 is less than a distance Q2 between the centers of any two adjacent first sub-pixels 11 located in the second display region 102. In some embodiments, the distance between the centers of any two adjacent second sub-pixels 12 located in the first display region 101 is less than the distance between the centers of any two adjacent second sub-pixels 12 located in the second display region 102. In some embodiments, the distance between the centers of any two adjacent third sub-pixels 13 located in the first display region 101 is less than that the distance between the centers of any two adjacent third sub-pixels 13 located in the third display region 102.

The term “adjacent” used herein to define the relationship between two sub-pixels of the same type (for example, any two adjacent first sub-pixels 11) only refers to one sub-pixel and the other sub-pixel closest to it among the plurality of sub-pixels of this type (for example, one first sub-pixel 11 and the other first sub-pixel 11 closest to it, among the plurality of first sub-pixels 11), rather than meaning that two sub-pixels of the same type (for example, two first sub-pixels 11) must be directly adjacent to each other. For example, the second sub-pixel 12 and/or the third sub-pixel 13 may be provided between two adjacent first sub-pixels 11. Two adjacent second sub-pixels 12 and two adjacent third sub-pixels 13 also have similar meanings to the above, which will not be repeatedly described.

In some embodiments, each sub-pixel includes a first electrode portion 121, a light-emitting function portion 131, and a second electrode portion 151. The light-emitting function portion 131 is provided on a side of the first electrode portion 121 away from the substrate 110. The second electrode portion 151 is provided on a side of the light-emitting function portion 131 away from the substrate 110.

The first electrode portion 121 is an anode of the sub-pixel. The light-emitting function portion 131 is the light-emitting portion of the sub-pixel. Specifically, the light-emitting function portion 131 includes an organic light-emitting layer, a hole injection layer, a hole transport layer, an electron transport layer, and an electron injection layer. The second electrode portion 151 is a cathode of the sub-pixel.

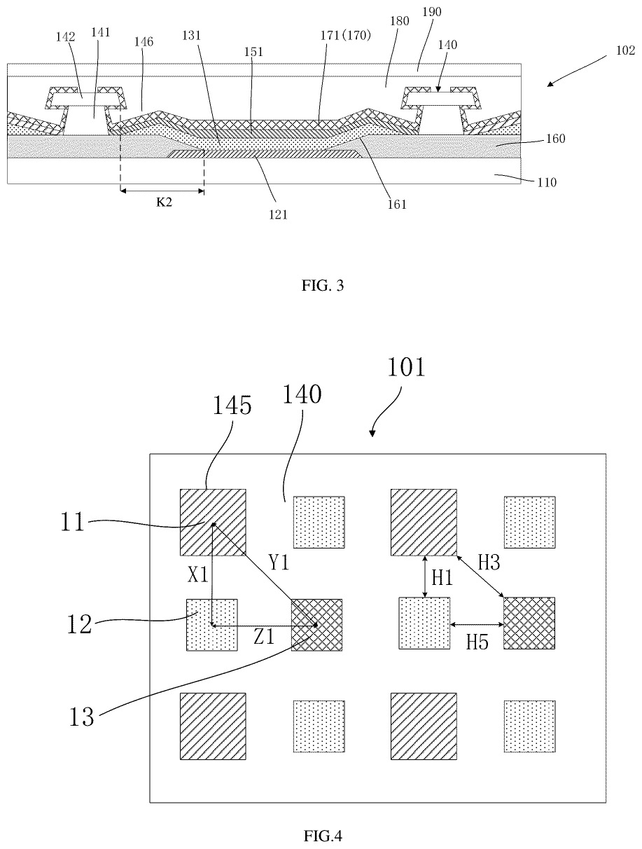

In some embodiments, as shown in FIGS. 2 and 3, the display panel 100 further includes a pixel definition layer 160. The pixel definition layer 160 is provided on the same side of the substrate 110 with the partition structure 140. For example, the pixel definition layer 160 is provided between the partition structure 140 and the substrate 110. The pixel definition layer 160 has a plurality of pixel definition openings 161. The light-emitting function portion 131 is at least partially located within the pixel definition opening 161.

The pixel definition opening 161 is configured to expose the first electrode portion 121, so that at least part of the light emitting function portion 131 is provided on the first electrode portion 121 through the pixel definition opening 161. In some embodiments, the pixel definition opening 161 located in the first display region 101 is provided at the center of the first opening 145, which is beneficial to ensure the uniformity of light emission of the light-emitting function portion 131 in the first display region 101. In some embodiments, the pixel definition opening 161 located in the second display region 102 is provided at the center of the second opening 146, which is beneficial to ensure the uniformity of light emission of the light-emitting function portion 131 in the second display region 102. In some embodiments, the pixel definition layer 160 is an electrical insulator. The first electrode portions 121 belonging to the plurality of sub-pixels are electrically insulated from each other through the pixel definition layer 160.

In some embodiments, the area of the pixel definition opening 161 in which the light-emitting function portion 131 corresponding to the first sub-pixel 11 is provided in the first display region 101 is less than or equal to the area of the pixel definition opening 161 in which the light-emitting function portion 131 corresponding to the first sub-pixel 11 is provided in the second display region 102. In some embodiments, the area of the pixel definition opening 161 in which the light-emitting function portion 131 corresponding to the second sub-pixel 12 is provided in the first display region 101 is less than or equal to the area of the pixel definition opening 161 in which the light-emitting function portion 131 corresponding to the second sub-pixel 12 is provided in the second display region 102. In some embodiments, the area of the pixel definition opening 161 in which the light-emitting function portion 131 corresponding to the third sub-pixel 12 is provided in the first display region 101 is less than or equal to the area of the pixel definition opening 161 in which the light-emitting function portion 131 corresponding to the third sub-pixel 13 is provided in the second display region 102.

In some embodiments, the partition structure 140 includes a conductive material. The second electrode portion 151 is electrically connected to the partition structure 140. As such, the second electrode portions 151 of different sub-pixels can be electrically connected through the partition structure 140. In this way, the cathodes of the plurality of sub-pixels are electrically connected to each other, which is beneficial to reduce the quantity of cathode wirings connected to the cathode. Since the quantity of cathode wirings can affect the size of the bezel of the display panel 100, it is beneficial to achieve a narrow bezel design of the display panel 100.

In some embodiments, the first openings 145 are arranged in one-to-one correspondence with the pixel definition openings 161 located in the first display region 101; and an orthographic projection of the pixel definition opening 161 located in the first display region 101 onto the substrate 110 is located within an orthographic projection of the corresponding first opening 145 onto substrate. The second openings 146 are arranged in one-to-one correspondence with the pixel definition openings 161 located in the second display region 102; and an orthographic projection of the pixel definition opening 161 located in the second display region 102 onto the substrate 110 is located within an orthographic projection of the corresponding second opening 146 onto substrate. In the first display region 101, the first openings 145 are in a one-to-one correspondence with the pixel definition openings 161 located in the first display region 101. In the second display region 102, the second openings 146 are in a one-to-one correspondence with the pixel definition opening 161 located in the second display region 102. That is, each sub-pixel corresponds to a light-emitting function portion 131, and any two adjacent sub-pixels are isolated by the partition structure 140.

In some embodiments, as shown in FIGS. 2 and 3, a first distance K1 is defined between a boundary of the orthographic projection of the pixel definition opening 161 onto the substrate 110 in the first display region 101 and a boundary of the orthographic projection of the corresponding first opening 145 onto the substrate 10. A second distance K2 is defined between a boundary of the orthographic projection of the pixel definition opening 161 onto the substrate 110 in the second display region 102 and a boundary of the orthographic projection of the corresponding second opening 146 onto the substrate 10. In one embodiment, K1=K2, i.e., the first distance K1 is equal to the second distance K2. That is, the size of the pixel definition opening 161 is positively correlated with the size of the partition opening. Since the partition structure has a limiting effect on the maximum light emission angles of the sub-pixels, the maximum light emission angles of different sub-pixels can be kept the same, which is beneficial to improve the uniformity of the display effect of the display panel.

In some embodiments, the second display region 102 is provided around at least part of the first display region 101. Therefore, the display panel 100 can be applied to smart watches.

In some embodiments, the second display region 102 is shaped as a closed or unclosed ring, so that the second display region 102 can be configured to surround at least part of the first display region 101.

In some embodiments, the first display region 101 is shaped as a circle. The circular first display region 101 can be used as the main display region, and the annular second display region 102 located on the periphery of the first display region 101 can be used as the secondary display region. For example, the main display region can be used to display relatively important information (such as time, short messages, call records, exercise records, etc.), and the secondary display region can be used to display secondary auxiliary information (such as date, weather, etc.).

In some embodiments, as shown in FIGS. 2 and 3, the partition structure 140 includes an isolating body 141 and a blocking portion 142. The blocking portion 142 is located on a side of the isolating body 141 away from the substrate 110. An orthographic projection of the top surface of the isolating body 141 onto the substrate 110 is located within an orthographic projection of the bottom surface of the blocking portion 142 onto the substrate 110. The isolating body 141 is mainly configured to isolate the light-emitting function portions 131 of different sub-pixels, and to isolate the second electrode portions 151 of different sub-pixels. The blocking portion 142 is located on the side of the isolating body 141 away from the substrate 110, and the orthographic projection of the top surface of the isolating body 141 onto the substrate 110 is located within the orthographic projection of the bottom surface of the blocking portion 142 onto the substrate 110, that is, there is a certain distance from the edge of the bottom surface of the blocking portion 142 to the edge of the top surface of the isolating body 141, thereby forming a step structure between the bottom surface of the blocking portion 142 and the top surface of the isolating body 141. The step structure is beneficial to enable the luminescent material layers formed on different sides of the partition structure 140 to be isolated from each other during the evaporation process.

In some embodiments, the isolating body 141 includes a conductive material. The second electrode portion 151 is electrically connected to the isolating body 141, thereby allowing electrical conduction between the second electrode portions 151 of different sub-pixels through the isolating body 141.

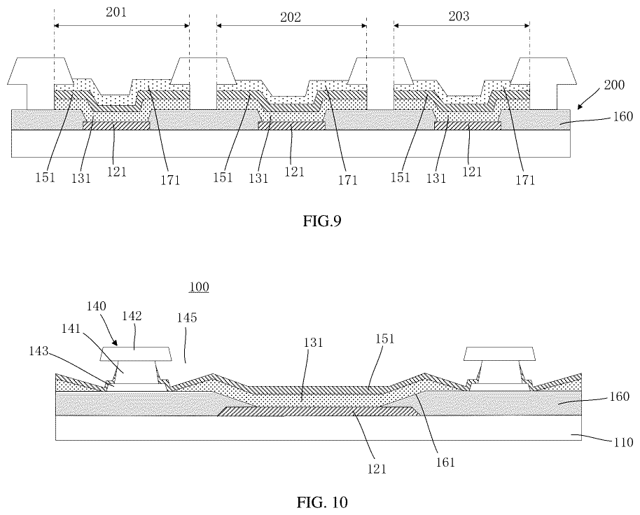

In some embodiments, as shown in FIG. 10, the partition structure 140 may further include a bearing portion 143. The bearing portion 143 is located on a side of the isolating body 141 adjacent to the substrate 110. The orthographic projection of the bottom surface of the isolating body 141 onto the substrate 110 is located within an orthographic projection of the top surface of the bearing portion 143 onto the substrate 110. The bearing portion 143 includes a conductive material. The second electrode portion 151 is electrically connected to the bearing portion 143. Through such arrangement, the size of the top surface of the bearing portion 143 is greater than the size of the bottom surface of the isolating body 141. Since the partition structure 140 further includes the bearing portion 143, the second electrode portion 151 first climbs across the bearing portion 143 and then is connected to the isolating body 141, thereby reducing the climbing angle of the second electrode portion 151, which is beneficial to improve the connection stability between the second electrode portion 151 and the isolating body 141. In addition, the bearing portion 143 also includes the conductive material, and the second electrode portion 151 is also electrically connected to the bearing portion 143. In this way, even if there is a disconnection between the second electrode portion 151 and the isolating body 141, the electrical connection between the second electrode portion 151 and the partition structure 140 can be ensured, which can further prevent electrical connection failure and improve the performance stability of the display panel 100.

In some embodiments, the second electrode portion 151 covers part of the top surface and at least part of the side surface of the bearing portion 143. That is, the second electrode portion 151 may cover a part of the side surface of the bearing portion 143, or may cover the entire side surface of the bearing portion 143. It should be understood that the greater the surface area of the second electrode portion 151 covering the bearing portion 143, the better the stability of the electrical connection between the second electrode portion 151 and the bearing portion 143.

In some embodiments, the display panel 100 further includes a first packaging layer 170. The first packaging layer 170 includes a plurality of packaging portions 171 arranged at intervals. The packaging portions 171 are configured to package the light-emitting function portion 131. With such arrangement, the packaging portions 171 can package and protect the light-emitting function portions 131 in a one-to-one correspondence.

In some embodiments, the display panel 100 further includes a second packaging layer 180. The second packaging layer 180 is provided on a side of the first packaging layer 170 away from the substrate 110. The second packaging layer 180 covers the first packaging layer 170 and the top surface of the partition structure 140. The first packaging layer 170 packages the light-emitting function portions 131 one by one through the first packaging portions 171 arranged at intervals. The second packaging layer 180 can be an entire surface package, that is, the second packaging layer 180 entirely covers the plurality of or all of the first packaging layers 170 and the lower second electrode portion 151, the light-emitting function portion 131, and the first electrode portion 121, thereby further improving the packaging performance.

In some embodiments, the display panel 100 may further include a third packaging layer 190. The third packaging layer 190 is provided on a side of the second packaging layer 180 away from the substrate 110. As such, the first packaging layer 170, the second packaging layer 180, and the third packaging layer 190 implement multi-layer packaging, which further improves packaging performance.

Specifically, the first packaging layer 170 and the third packaging layer 190 may be inorganic film layers, and the second packaging layer 180 may be an organic film layer. The inorganic film layer mainly plays the role of isolating water vapor and air, and the organic film layer is mainly configured to provide flexibility. In addition, the second packaging layer 180 is an organic film layer, and can also perform planarization for the first packaging layer 170.

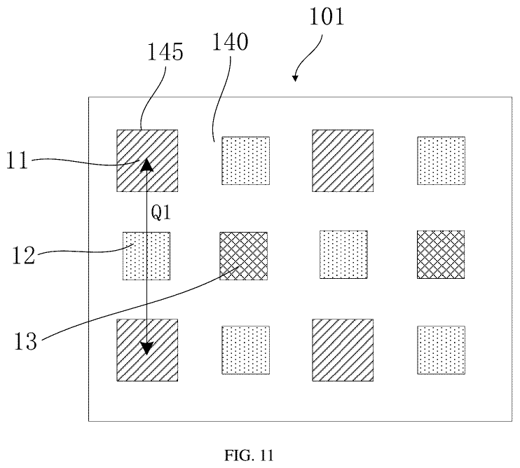

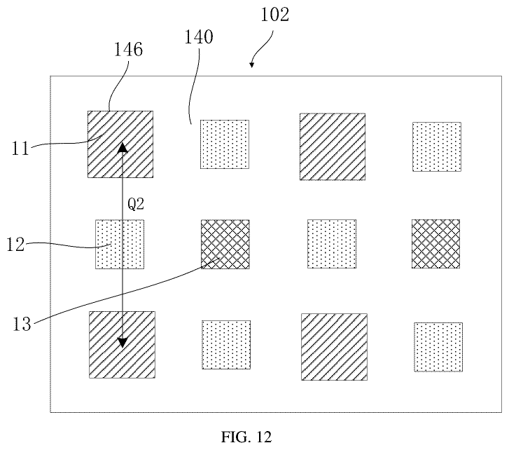

Embodiments of a second aspect of the present disclosure provide a display panel 100. As shown in FIGS. 11 and 12, the display panel 100 has a first display region 101 and a second display region 101. The display panel 100 includes a substrate 110, a plurality of sub-pixels configured to form a plurality of pixel units, and a partition structure 140. The plurality of sub-pixels are provided on the substrate 110. The partition structure 140 is provided on a side of the substrate 110. The partition structure 140 defines a plurality of partition openings. The partition openings include a first opening 145 located in the first display region 101 and a second opening 146 located in the second display region 102. The plurality of sub-pixels are respectively provided in the first opening 145 and the second opening 145. The plurality of sub-pixels include a plurality of first sub-pixels 11. A distance Q1 between the centers of two adjacent first sub-pixels 11 located in the first display region 101 is less than a distance Q2 between the centers of two adjacent first sub-pixels 11 located in the second display region 102. In one embodiment, the plurality of sub-pixels include a plurality of second sub-pixels 12. A distance between the centers of the two adjacent second sub-pixels 12 located in the first display region 101 is less than a distance between the centers of two adjacent second sub-pixels 12 located in the second display region 102. In one embodiment, the plurality of sub-pixels include a plurality of third sub-pixels 13. A distance between the centers of two adjacent third sub-pixels 13 located in the first display region 101 is less than a distance between the centers of two adjacent third sub-pixels 13 located in the second display region 102.

In the display panel 100 according to the embodiment of the present disclosure, since the distance Q1 between the centers of two adjacent sub-pixels of the same color (for example, two adjacent first sub-pixels 11) located in the first display region 101 is less than the distance Q2 between the centers of two adjacent sub-pixels of the same color (for example, the first sub-pixel 11) located in the second display region 102, the sub-pixels of the same color in the first display region 101 are more densely distributed than the sub-pixels of the same color in the second display region 102, so that the PPI of the first display region 101 is greater than the PPI of the second display region 102. When the display panel 100 is in use, the first display region 101 can be used as a main display region for displaying relatively important information, and the second display region 102 can be used as a secondary display for displaying secondary auxiliary information. In the display panel 100 according to the embodiment of the present disclosure, the first display region 101 and the second display region 102 have different PPIs, which is beneficial to reduce the production cost of the display panel 100.

In some embodiments, the distance Q1 between the centers of any two adjacent first sub-pixels 11 located in the first display region 101 is less than the distance Q2 between the centers of any two adjacent first sub-pixels 11 located in the second display region 102. In one embodiment, the distance between the centers of any two adjacent second sub-pixels 12 located in the first display region 101 is less than the distance between the centers of any two adjacent second sub-pixels 12 located in the second display region 102. In one embodiment, the plurality of sub-pixels include third sub-pixels 13, and the distance between the centers of any two adjacent third sub-pixels 13 located in the first display region 101 is less than the distance between the centers of any two adjacent third sub-pixels 13 located in the second display region 102.

Embodiments of a third aspect of the present disclosure provides a display panel 100. Referring to FIGS. 1, 4 and 5, the display panel 100 has a first display region 101 and a second display region 102. The display panel 100 includes a substrate 110, and a plurality of sub-pixels configured to form a plurality of pixel units. The plurality of sub-pixels are provided on the substrate 110. The plurality of sub-pixels include first sub-pixels 11 and second sub-pixels 12. A distance X1 between the centers of the first sub-pixel 11 and the adjacent second sub-pixel 12 located in the first display region 101 is less than a distance X2 between the centers of the first sub-pixel 11 and the adjacent second sub-pixel 12 located in the second display region 101.

In the display panel 100 according to the embodiment of the present disclosure, since the distance X1 between the centers of the first sub-pixel 11 and the second sub-pixel 12 located in the first display region 101 is less than the distance X2 between the centers of the first sub-pixel 11 and the second sub-pixel 12 located in the second display region 101, at least one of the first sub-pixels 11 and the second sub-pixels 12 in the first display region 101 are more densely distributed than the corresponding sub-pixels of the same color in the second display region 102, so that the PPI of the first display region 101 is greater than the PPI of the second display region 102. When the display panel 100 is in use, the first display region 101 can be used as the main display region for displaying relatively important information, and the second display region 102 can be used as the secondary display for displaying secondary auxiliary information. In the display panel 100 according to the embodiments of the present disclosure, the first display region 101 and the second display region 102 have different PPI, which is beneficial to reduce the production cost of the display panel 100.

In some embodiments, a distance X1 between the centers of the first sub-pixel 11 and the adjacent second sub-pixel 12 located in the first display region 101 is less than a distance X2 between the centers of the first sub-pixel 11 and the adjacent second sub-pixel 12 located in the first display region 102.

Embodiments of a fourth aspect of the present disclosure provides a display device, which includes the display panel 100 according to any of the above embodiments. The display device may be, for example, a display, a television, a digital camera, a mobile phone, a tablet, a navigator, or any other product or component with a display function.

The display device according to the embodiment of the present disclosure has the same inventive concept as the display panel 100 according to the above-mentioned embodiments. The display device can also obtain all the technical effects brought by the above-mentioned display panel 100, and which is not repeatedly described.

The technical features of the above-mentioned embodiments can be combined arbitrarily. In order to make the description concise, not all possible combinations of the technical features are described in the embodiments. However, as long as there is no contradiction in the combination of these technical features, the combinations should be considered as in the scope of the present disclosure.

The above-described embodiments are only several implementations of the present disclosure, and the descriptions are relatively specific and detailed, but they should not be construed as limiting the scope of the present disclosure. It should be understood by those of ordinary skill in the art that various variants and improvements can be made without departing from the concept of the present disclosure, and all fall within the protection scope of the present disclosure. Therefore, the patent protection of the present disclosure shall be subjected to the appended claims.

What is claimed is:

1. A display panel, having a first display region and a second display region, the display panel comprising:
a substrate;
a plurality of sub-pixels provided on the substrate; and
a partition structure provided on a side of the substrate, wherein the partition structure defines a plurality of partition openings, the partition openings comprising a first opening located in the first display region and a second opening located in the second display region, wherein the plurality of sub-pixels are provided in the first opening and the second opening, respectively,
wherein the plurality of sub-pixels comprise a first sub-pixel and a second sub-pixel, a distance between centers of the first sub-pixel and the adjacent second sub-pixel located in the first display region is less than a distance between centers of the first sub-pixel and the adjacent second sub-pixel located in the second display region.

2. The display panel according to claim 1, wherein the plurality of sub-pixels further comprise a third sub-pixel;
a distance between centers of the first sub-pixel and the adjacent third sub-pixel located in the first display region is less than a distance between centers of the first sub-pixel and the adjacent third sub-pixel located in the second display region;
a distance between centers of the second sub-pixel and the adjacent third sub-pixel located in the first display region is less than a distance between centers of the second sub-pixel and the adjacent third sub-pixel located in the second display region.

3. The display panel according to claim 2, wherein in the first display region, a first spacing is defined between the first opening in which the first sub-pixel is provided and the adjacent first opening in which the second sub-pixel is provided;
in the second display region, a second spacing is defined between the second opening in which the first sub-pixel is provided and the adjacent second opening in which the second sub-pixel is provided;
the first spacing is less than the second spacing; in the first display region, a third spacing is defined between the first opening in which the first sub-pixel is provided and the adjacent first opening in which the third sub-pixel is provided;
in the second display region, a fourth spacing is defined between the second opening in which the first sub-pixel is provided and the adjacent second opening in which the third sub-pixel is provided; the third spacing is less than the fourth spacing; in the first display region, a fifth spacing is defined between the first opening in which the second sub-pixel is provided and the adjacent first opening in which the third sub-pixel is provided; in the second display region, a sixth spacing is defined between the second opening in which the second sub-pixel is provided and the adjacent second opening in which the third sub-pixel is provided;
the fifth spacing is less than the sixth spacing.

4. The display panel according to claim 3, wherein an area of the first opening in which the first sub-pixel is provided is less than or equal to an area of the second opening in which the first sub-pixel is provided;
an area of the first opening in which the second sub-pixel is provided is less than or equal to an area of the second opening in which the second sub-pixel is provided;
an area of the first opening in which the third sub-pixel is provided is less than or equal to an area of the second opening in which the third sub-pixel is provided.

5. The display panel according to claim 2, wherein a distance between centers of two adjacent first sub-pixels located in the first display region is less than a distance between centers of two adjacent first sub-pixels located in the second display region;
a distance between centers of two adjacent second sub-pixels located in the first display region is less than a distance between centers of two adjacent second sub-pixels located in the second display region;
a distance between centers of two adjacent third sub-pixels located in the first display region is less than that a distance between centers of two adjacent third sub-pixels located in the second display region.

6. The display panel according to claim 1, wherein each sub-pixel comprises:
a first electrode portion;
a light-emitting function portion provided on a side of the first electrode portion away from the substrate; and
a second electrode portion provided on a side of the light-emitting function portion away from the substrate.

7. The display panel according to claim 6, further comprising a pixel definition layer provided on the same side of the substrate with the partition structure, wherein the pixel definition layer comprises a plurality of pixel definition openings, and the light-emitting function portion is at least partially located within the pixel definition opening.

8. The display panel according to claim 7, wherein an area of the pixel definition opening in which the light-emitting function portion corresponding to the first sub-pixel is provided in the first display region is less than or equal to an area of the pixel definition opening in which the light-emitting function portion corresponding to the first sub-pixel is provided in the second display region;
an area of the pixel definition opening in which the light-emitting function portion corresponding to the second sub-pixel is provided in the first display region is less than or equal to an area of the pixel definition opening in which the light-emitting function portion corresponding to the second sub-pixel is provided in the second display region;
an area of the pixel definition opening in which the light-emitting function portion corresponding to the third sub-pixel is provided in the first display region is less than or equal to an area of the pixel definition opening in which the light-emitting function portion corresponding to the third sub-pixel is provided in the second display region.

9. The display panel according to claim 6, wherein the partition structure comprises a conductive material, and the second electrode portion is electrically connected to the partition structure.

10. The display panel according to claim 7, wherein the first openings are arranged in correspondence with the pixel definition openings located in the first display region, and an orthographic projection of the pixel definition opening located in the first display region onto the substrate is located within an orthographic projection of the corresponding first opening onto substrate;
the second openings are arranged in correspondence with the pixel definition openings located in the second display region, and an orthographic projection of the pixel definition opening located in the second display region onto the substrate is located within an orthographic projection of the corresponding second opening onto substrate.

11. The display panel according to claim 10, wherein a boundary of the orthographic projection of the pixel definition opening onto the substrate in the first display region and a boundary of the orthographic projection of the corresponding first opening onto the substrate have a first distance defined therebetween;
a boundary of the orthographic projection of the pixel definition opening onto the substrate in the second display region and a boundary of the orthographic projection of the corresponding second opening onto the substrate have a second distance defined therebetween;
and wherein the first distance is equal to the second distance.

12. The display panel according to claim 6, wherein the partition structure comprises an isolating body and a blocking portion located on a side of the isolating body away from the substrate; wherein an orthographic projection of a top surface of the isolating body onto the substrate is located within an orthographic projection of a bottom surface of the blocking portion onto the substrate;
the isolating body comprises a conductive material; the second electrode portion is electrically connected to the isolating body.

13. The display panel according to claim 12, wherein the partition structure further comprises a bearing portion located on a side of the isolating body adjacent to the substrate; the orthographic projection of the bottom surface of the isolating body onto the substrate is located within an orthographic projection of a top surface of the bearing portion onto the substrate;
the bearing portion comprises a conductive material; the second electrode portion is electrically connected to the bearing portion.

14. The display panel according to claim 13, wherein the second electrode portion covers part of the top surface and at least part of side surface of the bearing portion.

15. The display panel according to claim 1, wherein the second display region surrounds at least part of the first display region.

16. The display panel according to claim 15, wherein the second display region is shaped as a closed or unclosed ring, and the first display region is shaped as circle.

17. A display panel having a first display region and a second display region, the display panel comprising:
a substrate;
a plurality of sub-pixels provided on the substrate; and
a partition structure provided on a side of the substrate, wherein the partition structure defines a plurality of partition openings, the partition openings comprising a first opening located in the first display region and a second opening located in the second display region, wherein the plurality of sub-pixels are provided in the first openings and the second opening, respectively,
wherein the plurality of sub-pixels comprise a plurality of first sub-pixels; a distance between centers of two adjacent first sub-pixels located in the first display region is less than a distance between centers of two adjacent first sub-pixels located in the second display region.

18. The display panel according to claim 17, wherein the plurality of sub-pixels comprise a plurality of second sub-pixels, a distance between centers of two adjacent second sub-pixels located in the first display region is less than a distance between centers of two adjacent second sub-pixels located in the second display region;
the plurality of sub-pixels comprise a plurality of third sub-pixels; a distance between centers of two adjacent third sub-pixels located in the first display region is less than a distance between centers of two adjacent third sub-pixels located in the second display region.

19. A display panel having a first display region and a second display region, the display panel comprising:
a substrate; and
a plurality of sub-pixels provided on the substrate;
wherein the plurality of sub-pixels comprise a first sub-pixel and a second sub-pixel; a distance between centers of the first sub-pixel and the adjacent second sub-pixel located in the first display region is less than a distance between centers of the first sub-pixel and the adjacent second sub-pixel located in the second display region.
